(19) United States
(12) Patent Application Publication
(10) Pub. No.: US 2026/0064020 A1
(43) Pub. Date: Mar. 5, 2026

(54) EUV MASK PARTICLE REMOVING METHODS AND SYSTEMS

(71) Applicant: Taiwan Semiconductor Manufacturing Company, Ltd., Hsinchu (TW)

(72) Inventors: Li-Chun HUNG, Hsinchu (TW); Chia-Shih LIN, Hsinchu (TW); Chien-Hung LAI, Hsinchu (TW)

(73) Assignee: Taiwan Semiconductor Manufacturing Company, Ltd., Hsinchu (TW)

(21) Appl. No.: 18/819,732

(22) Filed: Aug. 29, 2024

(51) Int. Cl. G03F 7/00; B08B 3/08; B08B 5/02; G03F 1/22

(52) U.S. Cl. CPC G03F 7/70925; B08B 3/08; B08B 5/02; G03F 1/22; G03F 7/70033

(57) ABSTRACT

A method for removing contaminant particles on a surface of a mask includes collecting an image of the mask with the contaminant particles on the surface of the mask, and determining a type of the contaminant particles based on the image of the mask. The method further includes performing a particle-removing process corresponding to the type of the contaminant particles on the surface of the mask, and determining if the contaminant particles are removed from the surface of the mask by the particle-removing process. The method also includes associating the particle-removing process with the type of the contaminant particles when the contaminant particles are removed from the surface of the mask by the particle-removing process.

### BACKGROUND

Debris particles can reduce the yield of photolithography operations by undesirably shielding portions of a mask pattern. It is, therefore, desirable to maintain a clean environment in locations and routes where masks pass through during the lithography process such as tool grippers, chambers, mask holders, etc. In particular, the ability to produce high-quality microelectronic devices and reduce yield losses is dependent upon maintaining the surfaces of critical components substantially defect-free. This would include maintaining the surfaces free of contaminants, e.g., maintaining an ultra-clean surface and ensuring that contaminants are not deposited on the surface of the reticle or the mask. This is of particular concern as finer features are required on the microelectronic device. The types of contaminants can be any arbitrary combination depending on the environment and the vacuum condition. The contaminants could be introduced from operations, such as etching byproducts in the mask-making process, organic hydrocarbon contaminants, any kind of fall-on dust, outgassing from steel, and so on.

The type of contaminant particles on the mask is different during each fabrication process. The mask may be exposed to abrasive tools or unknown rust in the fabrication processes. Tin balls with sizes ranging from 50 nm to 8000 nm may also be formed during an extreme ultraviolet (EUV) mask lithography process. A corresponding particle-removing process needs to be applied to the mask to effectively remove the contaminant particles from the mask. However, selecting an effective particle-removing process for the contaminant particles requires a lot of experience. Moreover, the analysis of the contaminant particles and determining the type of the contaminant particles is time-consuming and extends the repair cycle of the mask. Thus, improved methods of removing the contaminant particles from the mask are desirable.

### BRIEF DESCRIPTION OF THE DRAWING

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a schematic view of an EUV lithography system, according to embodiments of the disclosure.

FIG. 2 illustrates a diagram of the exposure of a substrate using a patterning mask, according to embodiments of the disclosure.

FIG. 3 illustrates a flow diagram of a method for removing contaminant particles from a patterning mask, according to embodiments of the disclosure.

FIG. 4 illustrates a block diagram for removing contaminant particles from the patterning mask, according to embodiments of the disclosure.

FIG. 5 illustrates a block diagram of an example artificial intelligence (AI) engine according to various aspects of the present disclosure.

FIG. 6 illustrates surface profiles of patterning masks, according to embodiments of the disclosure.

FIG. 7 illustrates surface spectrums of patterning masks, according to embodiments of the disclosure.

FIG. 8 illustrates a surface profile of a patterning mask, according to embodiments of the disclosure.

FIGS. 9A and 9B illustrate a computer system for implementing various methods, according to embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the term “being made of” may mean either “comprising” or “consisting of. ” In the present disclosure, a phrase “one of A, B and C” means “A, B and/or C” (A, B, C, A and B, A and C, B and C, or A, B and C), and does not mean one element from A, one element from B and one element from C, unless otherwise described.

In some embodiments, in a lithography system, e.g., an EUV lithography system, a beam of EUV radiation is generated by an EUV radiation source, and the beam of EUV radiation is directed to an exposure device for projecting layout patterns of patterning masks onto photoresist layers disposed on one or more wafers. In some embodiments, the exposure device includes or is coupled to a mask-handling system that includes a mask-holding mechanism, e.g., a mask stage. The mask handling system receives a patterning mask and mounts the patterning mask on the mask stage or alternatively removes the patterning mask from the mask stage and transfers the patterning mask out of the lithography system. The exposure device also includes optical components, e.g., mirrors and/or lenses, for projecting the beam of EUV radiation onto the patterning mask, e.g., a reflective patterning mask. The exposure device further includes optical components for projecting the layout patterns of the patterning mask onto a photoresist layer of a wafer.

Transferring patterning masks into the mask handling system and transferring the wafers into the wafer table may bring particles and organic material contamination onto the patterning masks. Thus, the patterning masks are regularly cleaned, e.g., during preventive maintenance (PM), to remove the particles and organic material contamination. In some embodiments, the patterning masks are manually cleaned. However, selecting an effective particle-removing process for the patterning mask to remove contaminant particles requires a lot of experience and is time-consuming. Moreover, the analysis of the contaminant particles and determining the type of the contaminant particles is also time-consuming and extends the repair cycle of the patterning mask. Embodiments of this disclosure provide improved methods and systems for removing the contaminant particles from the patterning mask, thereby reducing the mask cleaning time and the system maintenance time. Artificial intelligence (AI) may further assist with determining and identifying the type of contaminant particles on the mask, and further selecting a corresponding particle-removing process to remove the contaminant particles from the mask, such that the mask cleaning time and the system maintenance time can be reduced. Furthermore, the system can be trained with patterning masks having known contaminant particles to improve the accuracy and efficiency for identifying the type of contaminant particles and selecting the corresponding particle-removing process.

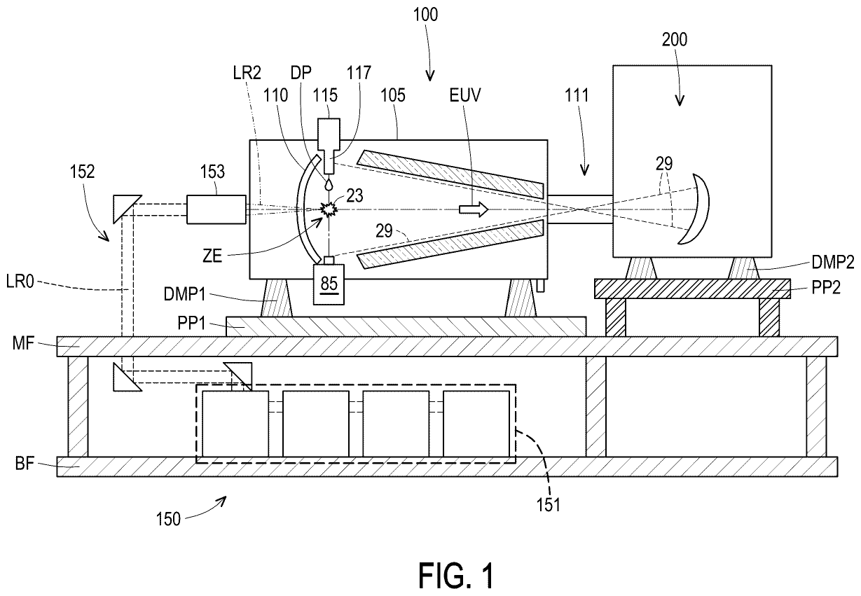

FIG. 1 illustrates a schematic view of an EUV lithography system with a laser-produced plasma (LPP) EUV radiation source in accordance with some embodiments of the present disclosure. The EUV lithography system includes an EUV radiation source 100 (an EUV light source) to generate EUV radiation, an exposure device 200, such as a scanner, and an excitation laser source 150. As shown in FIG. 1, in some embodiments, the EUV radiation source 100 and the exposure device 200 are installed on a main floor MF of a clean room, while the excitation laser source 150 is installed in a base floor BF located under the main floor. Each of the EUV radiation source 100 and the exposure device 200 are placed over pedestal plates PP1 and PP2 via dampers DMP1 and DMP2, respectively. The EUV radiation source 100 and the exposure device 200 are coupled to each other by a coupling mechanism, which may include a focusing unit 111. In some embodiments, a lithography system includes the EUV radiation source 100 and the exposure device 200.

The lithography system is an EUV lithography system designed to expose a photoresist layer by EUV light (also interchangeably referred to herein as EUV radiation). The resist layer is a material sensitive to the EUV light. The EUV lithography system employs the EUV radiation source 100 to generate EUV light, such as EUV light having a wavelength ranging between about 1 nm and about 50 nm. In one particular example, the EUV radiation source 100 generates an EUV light with a wavelength centered at about 13.5 nm. In the present embodiment, the EUV radiation source 100 utilizes a mechanism of laser-produced plasma (LPP) to generate the EUV radiation.

The exposure device 200 includes various reflective optical components, such as convex/concave/flat mirrors, a mask holding mechanism including a mask stage, and a wafer holding mechanism, e.g., a substrate holding mechanism or a wafer stage. In some embodiments, the mask stage is included in a mask handling system and the mask handling system, is included in or is coupled to the exposure device 200. In some embodiments, the wafer stage is included in a wafer table and the wafer table is included in or is coupled to the exposure device 200. The EUV radiation generated by the EUV radiation source 100 is guided by the reflective optical components onto a patterning mask secured on the mask stage. In some embodiments, the mask stage includes an electrostatic chuck (e-chuck) to secure the patterning mask. Because gas molecules absorb EUV light, the lithography system for the EUV lithography patterning is maintained in a vacuum or a low-pressure environment to avoid EUV intensity loss. A photoresist layer is disposed over the substrate. The EUV radiation generated by the EUV radiation source 100 is directed by the optical components to project the layout patterns of the patterning mask on the photoresist layer of the substrate. In some embodiments, after the exposure of the layout patterns of the mask on the photoresist layer of the substrate, the reticle is transferred out of the exposure device 200.

In the present disclosure, the terms patterning mask, photomask, mask, and reticle are used interchangeably. In addition, the terms resist and photoresist are used interchangeably. In some embodiments, the patterning mask is a reflective mask. In some embodiments, the patterning mask includes a substrate with a suitable material, such as a low thermal expansion material or fused quartz. In various examples, the material includes TiO₂ doped SiO₂, or other suitable material with low thermal expansion. The patterning mask includes multiple reflective layers (ML) deposited on the substrate. The ML includes a plurality of film pairs, such as molybdenum-silicon (Mo/Si) film pairs (e.g., a layer of molybdenum above or below a layer of silicon in each film pair). Alternatively, the ML may include molybdenum-beryllium (Mo/Be) film pairs or other suitable materials that are configurable to highly reflect the EUV light. The mask may further include a capping layer, such as ruthenium (Ru), disposed on the ML for protection. The patterning mask further includes an absorption layer, such as a tantalum boron nitride (TaBN) layer, deposited over the ML. The absorption layer is patterned to define a layer of an integrated circuit (IC).

The exposure device 200 includes projection optics modules for imaging the pattern of the patterning mask onto a semiconductor substrate with a resist coated thereon secured on a substrate stage of the exposure device 200. The projection optics modules generally include reflective optics. The EUV radiation (EUV light) directed from the mask, carrying the image of the pattern defined on the mask, is collected and directed by the projection optics modules, e.g., mirrors, thereby forming an image of the layout patterns of the patterning mask on the resist.

In various embodiments of the present disclosure, the semiconductor substrate is a semiconductor wafer, such as a silicon wafer or other type of wafer to be patterned. The semiconductor substrate is coated with a photoresist layer sensitive to the EUV light in presently disclosed embodiments. Various components including those described above are integrated together and are operable to perform lithography exposing processes. The lithography system may further include other modules or be integrated with (or be coupled with) other modules.

As shown in FIG. 1, the EUV radiation source 100 includes a droplet generator 115 and an LPP collector mirror 110, enclosed by a chamber 105. The droplet generator 115 generates a plurality of target droplets DP, which are supplied into chamber 105 through a nozzle 117. In some embodiments, the target droplets DP are tin (Sn), lithium (Li), or an alloy of Sn and Li. In some embodiments, the target droplets DP each have a diameter in a range from about 10 microns (μm) to about 100 μm. For example, in an embodiment, the target droplets DP are tin droplets, each having a diameter of about 10 μm, about 25 μm, about 50μm, or any diameter between these values. In some embodiments, the target droplets DP are supplied through the nozzle 117 at a rate in a range from about 50 droplets per second (i.e., an ejection-frequency of about 50 Hz) to about 50,000 droplets per second (i.e., an ejection-frequency of about 50 kHz). For example, in an embodiment, target droplets DP are supplied at an ejection frequency of about 50 Hz, about 100 Hz, about 500 Hz, about 1 kHz, about 10 kHz, about 25 kHz, about 50 kHz, or any ejection frequency between these frequencies. The target droplets DP are ejected through nozzle 117 and into a zone of excitation ZE (e.g., a target droplet location) at a speed in a range from about 10 meters per second (m/s) to about 100 m/s in various embodiments. For example, in an embodiment, the target droplets DP have a speed of about 10 m/s, about 25 m/s, about 50 m/s, about 75 m/s, about 100 m/s, or at any speed between these speeds.

The excitation laser beam LR2 generated by the excitation laser source 150 is a pulsed beam. The laser pulses of laser beam LR2 are generated by the excitation laser source 150. The excitation laser source 150 may include a laser generator 151, laser guide optics 152, and a focusing apparatus 153. In some embodiments, the laser generator 151 includes a carbon dioxide (CO₂) or a neodymium-doped yttrium aluminum garnet (Nd: YAG) laser source with a wavelength in the infrared region of the electromagnetic spectrum. For example, the laser source 150 has a wavelength of 9.4 μm or 10.6 μm in an embodiment. The laser light beam LR0 generated by the excitation laser source 150 is guided by the laser guide optics 152 and focused, by the focusing apparatus 153, into the excitation laser beam LR2 that is introduced into the EUV radiation source 100. In some embodiments, in addition to CO₂ and Nd: YAG lasers, the laser beam LR2 is generated by a gas laser including an excimer gas discharge laser, helium-neon laser, nitrogen laser, transversely excited atmospheric (TEA) laser, argon ion laser, copper vapor laser, KrF laser or ArF laser; or a solid state laser including Nd: glass laser, ytterbium-doped glasses, or ceramics laser, or ruby laser. In some embodiments, a non-ionizing laser beam LR1 (not shown) is also generated by the excitation laser source 150 and the laser beam LR1 is also focused by the focusing apparatus 153 to pre-heat a given target droplet by generating a pre-heat laser pulse.

In some embodiments, the excitation laser beam LR2 includes the pre-heat laser pulse and a main laser pulse. In such embodiments, the pre-heat laser pulse (interchangeably referred to herein as the 37 pre-pulse) is used to heat (or pre-heat) the given target droplet to create a low-density target plume with multiple smaller droplets, which is subsequently heated (or reheated) by the main laser pulse from the main laser, to generate increased emission of EUV light compared to when the pre-heat laser pulse is not used.

In various embodiments, the pre-heat laser pulses have a spot size of about 100 μm or less, and the main laser pulses have a spot size in a range of about 150 μm to about 300 μm. In some embodiments, the pre-heat laser and the main laser pulses have a pulse duration in the range from about 10 ns to about 50 ns, and a pulse frequency in the range from about 1 kHz to about 100 kHz. In various embodiments, the pre-heat laser and the main laser have an average power in the range from about 1 kilowatt (kW) to about 50 kW. The pulse frequency of the excitation laser beam LR2 is matched with the ejection frequency of the target droplets DP in an embodiment.

The laser beam LR2 is directed through windows (or lenses) into the zone of excitation ZE. The windows adopt a suitable material substantially transparent to the laser beams. The generation of the laser pulses is synchronized with the ejection of the target droplets DP through the nozzle 117. As the target droplets move through the excitation zone, the pre-pulses heat the target droplets and transform them into low-density target plumes. A delay between the pre-pulse and the main pulse is controlled to allow the target plume to form and expand to an optimal size and geometry. In various embodiments, the pre-pulse and the main pulse have the same pulse duration and peak power. When the main pulse heats the target plume, a high-temperature plasma plume 23 is generated. The plasma plume 23 emits EUV radiation 29, which is collected by the LPP collector mirror 110. The LPP collector mirror 110, an EUV collector mirror, further reflects and focuses the EUV radiation 29 for the lithography exposing processes performed through the exposure device 200. A droplet DP that does not interact with the laser pulses is captured by the droplet catcher 85. As shown in FIG. 1, the EUV radiation 29 from the LPP collector mirror 110 focuses at the focusing unit 111 between the EUV radiation source 100 and the exposure device 200. The EUV radiation 29 that enters from the focusing unit 111 into the exposure device 200 is consistent with EUV radiation that is originated from the focused point, e.g., a point source, in the focusing unit 111.

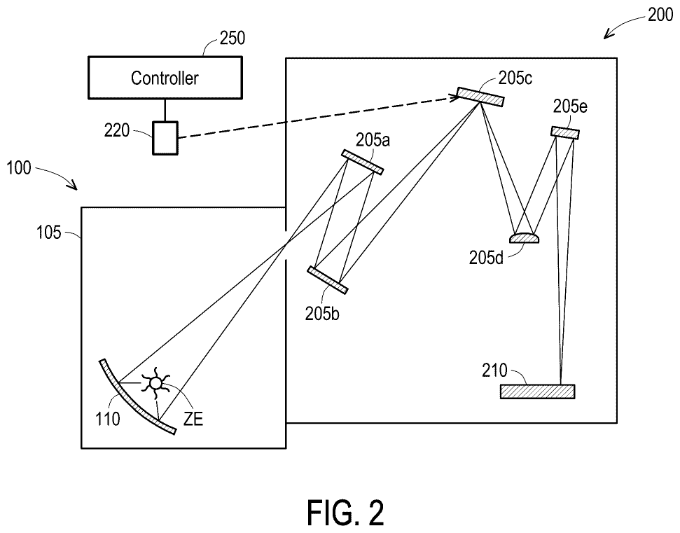

FIG. 2 illustrates a diagram of the exposure of a photoresist coated substrate 210 using a patterning mask 205c in accordance with some embodiments of the present disclosure. The exposure device 200 is an integrated circuit lithography tool such as a stepper, scanner, step and scan system, direct write system, device using a contact and/or proximity mask, etc., provided with one or more optics 205a, 205b, for example, to illuminate the patterning mask 205c with a beam of EUV light, to produce a patterned beam, and one or more reduction projection optics 205d, 205e, for projecting the patterned beam onto the substrate 210. A mechanical assembly (not shown) is provided for generating a controlled relative movement between substrate 210 and patterning mask 205c. As further shown in FIG. 2, the EUV lithography tool includes an EUV radiation source 100 including an EUV light radiator ZE emitting EUV light in a chamber 105 that is reflected by a LPP collector mirror 110 along a path into the exposure device 200 to irradiate the substrate 210.

In an embodiment, the patterning mask 205c includes a substrate with a suitable material, such as a low thermal expansion material or fused quartz. In some embodiments, the patterning mask 205c further includes a capping layer, such as ruthenium (Ru), disposed on the ML for protection. The mask further includes an absorption layer, such as a tantalum boron nitride (TaBN) layer, deposited over the ML. The absorption layer is patterned to define a layer of an integrated circuit (IC). Alternatively, another reflective layer may be deposited over the ML and is patterned to define a layer of an integrated circuit, thereby forming an EUV phase shift mask.

In various embodiments of the present disclosure, the substrate 210 is a semiconductor wafer, such as a silicon wafer or other type of wafer to be patterned.

In the EUV radiation source 100, the plasma caused by the laser application creates physical debris, such as ions, gases, and atoms of the droplet, as well as the desired EUV radiation. Some of the physical debris exits the chamber 105, enters the exposure device 200, and contaminates patterning mask 205c. In addition, the components of the lithography system including a mask handling system (not shown), the exposure device 200 for projecting the patterning mask to a wafer, and a wafer table (not shown) including one or more chucks for aligning and holding the wafers during the projection of the patterning mask may cause particles and organic material contamination when the lithographic process transfers the layout patterns of the patterning masks to the photoresist layer of the substrate. The physical debris, the particles, and the organic material contamination on the mask surface may cause non-uniformity in the critical dimension (CD) of the resist patterns generated on the wafer. The patterning mask may be cleaned to remove the contaminant particles during a mask repair process.

In some embodiments, as shown in FIG. 2, an imaging device 220 is configured to image the surface of the patterning mask 205c and generate an image of the surface of the patterning mask 205c. In addition, the imaging device 220 is electrically connected and/or coupled to a controller 250 configured to receive and process the generated image of the surface of the patterning mask 205c. In some embodiments, the controller 250 performs one or more image processing and/or image recognition algorithms on the generated image of the surface of the patterning mask 205c and determines the type of the contaminant particles on the surface of the patterning mask 205c. In some embodiments, the controller 250 is a microcontroller unit configured to perform one or more image processing and/or image recognition algorithms on the generated image of the surface of the patterning mask 205c and determine if the contaminant particles on the surface of the patterning mask 205c are removed.

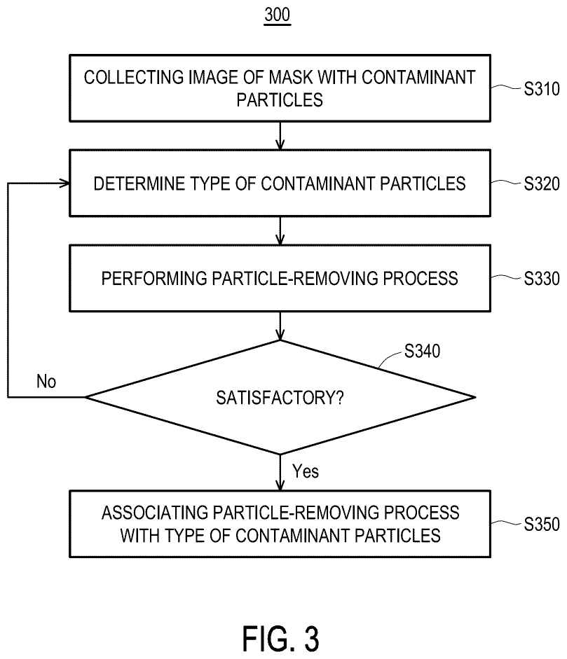

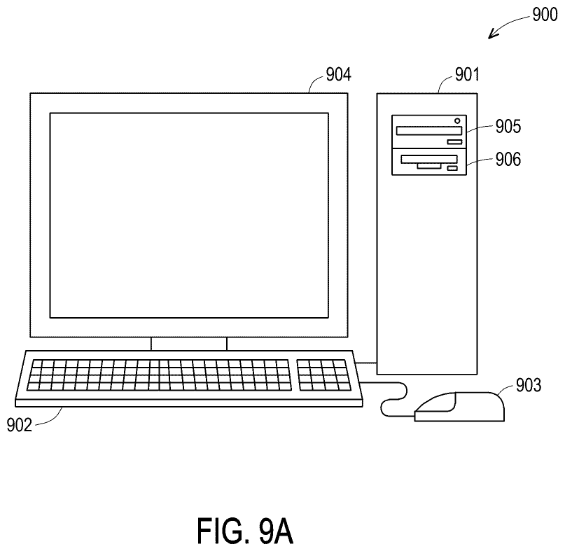

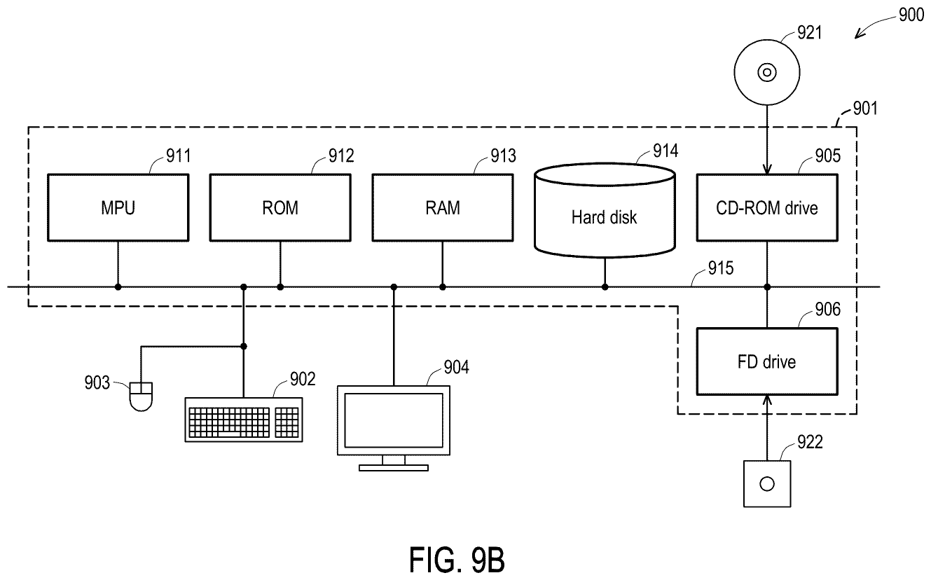

FIG. 3 illustrates a flow diagram of a method 300 for removing contaminant particles from the patterning mask 205c according to embodiments of the disclosure. The method 300 or a portion of the method 300 is performed by a controller (e.g., 250 of FIG. 2). In some embodiments, the method 300 or a portion of the method 300 is performed and/or is controlled by a computer system 900 described below with respect to FIGS. 9A and 9B. The method 300 is merely an example, and is not intended to limit the present disclosure and what is claimed.

Additional operations can be provided before, during, and after the method 300, and some operations described can be replaced, eliminated, or moved around for additional embodiments of the method 300.

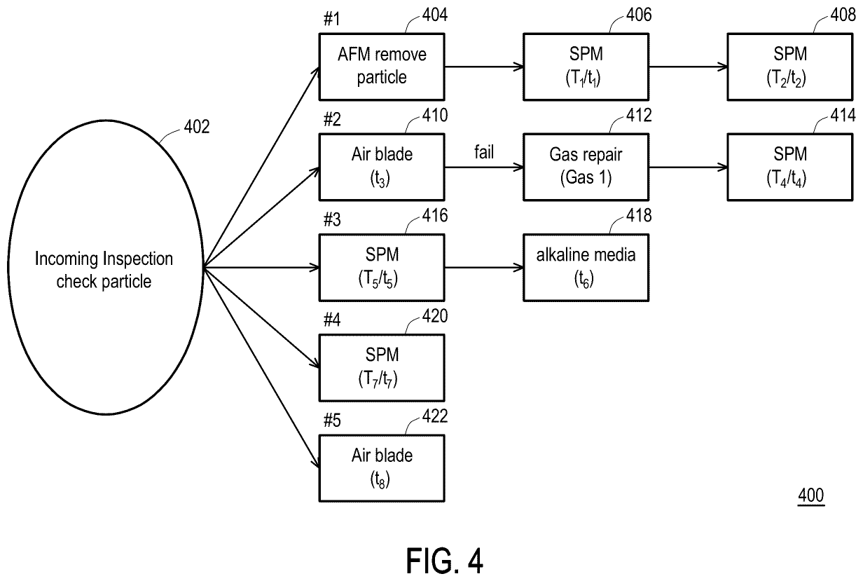

FIG. 4 illustrates a block diagram 400 for removing contaminant particles from the patterning mask 205c according to embodiments of the disclosure. For example, at block 402 of FIG. 4, the patterning mask 205c is ready to be inspected and cleaned.

In some embodiments, the method 300 includes an operation S310 as shown in FIG. 3. In operation S310, an image of the patterning mask 205c with contaminant particles on the surface of the patterning mask 205c is collected by the controller 250 as shown in FIG. 2.

In some embodiments, the imaging device 220 is configured to monitor and/or image the surface of the patterning mask 205c. In some embodiments, the imaging device 220 is configured to continuously or periodically monitor and/or image the surface of the patterning mask 205c.

In some embodiments, the imaging device 220 is a scanning electron microscope (SEM). The scanning electron microscope is configured to provide a surface profile and/or surface features of the patterning mask 205c.

In some embodiments, the imaging device 220 is an energy-dispersive X-ray spectroscope (EDX). The energy-dispersive X-ray spectroscope is configured to provide elemental compositions on the surface of the patterning mask 205c.

In some embodiments, the imaging device 220 is an atomic force microscope (AFM). For example, at block 404 of FIG. 4, the atomic force microscope is configured to provide a surface topography of the patterning mask 205c.

In some embodiments, the imaging device 220 includes other imaging sensors that provide surface information of the patterning mask 205c. In some embodiments, the imaging device 220 includes more than one of SEM, EDX, AFM, and/or the other imaging sensors.

In some embodiments, the method further includes an operation S320 as shown in FIG. 3. In operation S320, a type of the contaminant particles on the surface of the patterning mask 205c is determined based on the image of the patterning mask 205c.

In some embodiments, one or more attributes of the image of the patterning mask 205c are computed or otherwise determined as measured to determine the type of the contaminant particles on the surface of the patterning mask 205c based on the image of the patterning mask 205c. In some examples, the image of the patterning mask 205c is compared to an image of a corresponding mask which is not contaminated to determine the value of the attributes. The attributes determine and/or identify the type of the contaminant particles on the surface of the patterning mask 205c.

Various predefined attributes are used for determining and/or identifying the type of the contaminant particles on the surface of the patterning mask 205c. In some embodiments, the predefined attributes include the size of the contaminant particles, a shape of the contaminant particles, a viscosity of the contaminant particles, and/or components of the contaminant particles. In some embodiments, other attributes are used for determining and/or identifying the type of the contaminant particles.

In some embodiments, the method 300 further includes an operation S330 as shown in FIG. 3. In operation S330, a particle-removing process corresponding to the type of the contaminant particles is performed on the surface of the patterning mask 205c to remove the contaminant particles from the surface of the patterning mask 205c.

The contaminant particles may be physically removed from the surface of the patterning mask 203c. A particle-removing process corresponding to the type of the contaminant particles is performed on the surface of the patterning mask 205c to remove the contaminant particles from the surface of the patterning mask 205c.

In some embodiments, the contaminant particles have a size greater than 1 μm and the contaminant particles are pieces falling from pellicles onto the patterning mask 205c. In some embodiments, the corresponding particle-removing process is a sulfuric acid and hydrogen peroxide mixture (SPM) cleaning process. For example, as shown at block 406 of FIG. 4, a first SPM cleaning process is performed on the patterning mask 205c. The first SPM cleaning process may be applied to the patterning mask 205c for a time duration t₁ at a temperature T₁.

Additionally or alternatively, a second SPM cleaning process is performed on the patterning mask 205c to remove the contaminant particles from the patterning mask 205c as shown at block 408 of FIG. 4. The second SPM cleaning process may be applied to the patterning mask 205c for a time duration t₂ at a temperature T₂. In some embodiments, the time duration t₂ is longer than the time duration t₁. In some embodiments, the temperature T₂ is higher than the temperature T₁.

In some embodiments, the contaminant particles have a size smaller than or equal to 1 μm. In some embodiments, the contaminant particles are determined to be flat by atomic force microscope (AFM) or scanning electron microscope (SEM). The corresponding particle-removing process may be an air-blade cleaning process. For example, at block 410 of FIG. 4, the air-blade cleaning process uses an elongated pressurized air chamber, with a uniform continuous gap along one edge from which pressurized air exits in an evenly distributed laminar flow pattern. Forcing the exiting air through this narrow gap sends a high-impact air stream directly onto the surface of the patterning mask 205c to shear away the contaminant particles. In some embodiments, a time duration t₃ of the air-blade cleaning process is predetermined.

In some embodiments, the imaging device 220 is controlled by the controller 250 to monitor and/or image the surface of the patterning mask 205c after the air-blade cleaning process is performed on the patterning mask 205c. If the air-blade cleaning process fails to remove the contaminant particles from the patterning mask 205c, a gas-etching process is applied to the patterning mask 205c to remove the contaminant particles from the patterning mask 205c as shown at block 412 of FIG. 4. An SPM cleaning process is then performed on the patterning mask 205c to clean the gas and particle residues from the gas-etching process as shown at block 414 of FIG. 4. The SPM cleaning process may be applied to the patterning mask 205c for a time duration t₄ at a temperature T₄. In some embodiments, the time duration t₄ is different than the time duration t₁. In some embodiments, the temperature T₄ is different than the temperature T₁.

In some embodiments, the patterning mask 205c is damaged by the contaminant particles. An SPM cleaning process and an alkaline media cleaning process can be performed on the patterning mask 205c sequentially to remove the contaminant particles from the patterning mask 205c. The SPM cleaning process is applied to the patterning mask 205c for a time duration t₅ at a temperature T₅ as shown at block 416 of FIG. 4. In some embodiments, the time duration t₅ is different than the time duration t₁. In some embodiments, the temperature T₅ is different than the temperature T₁. Then the alkaline media cleaning process is applied to the patterning mask 205c by putting the patterning mask 205c into an alkaline solution for a time duration t₆ as shown at block 418 of FIG. 4.

In some embodiments, the contaminant particles have a size greater than 1 μm and the contaminant particles are determined to be flat by atomic force microscopy (AFM) and have oxidation states observed with energy-dispersive X-ray spectroscopy (EDX). For example, the contaminant particles are organic particles, which can be easily removed by a corresponding particle-removing process, such as a SPM cleaning process. For example, as shown at block 420 of FIG. 4, the SPM cleaning process is applied to the patterning mask 205c for a time duration t₇ at a temperature T₇.

In some embodiments, the contaminant particles have a size greater than 1 μm, the contaminant particles are flat, and do not look like a fiber as determined by atomic force microscopy (AFM) or scanning electron microscopy (SEM). For example, as shown at block 422 of FIG. 4, the corresponding particle-removing process may be an air-blade cleaning process. In some embodiments, a time duration t₈ of the air-blade cleaning process is predetermined.

In some embodiments, the method further includes an operation S340 as shown in FIG. 3. In operation S340, the controller 250 is further configured to determine if the contaminant particles are removed from the surface of the patterning mask 205c by the corresponding particle-removing process.

In some embodiments, the imaging device 220 is controlled by the controller 250 to monitor and/or image the surface of the patterning mask 205c after the corresponding particle-removing process is performed on the patterning mask 205c. The controller 250 is further configured to determine if the contaminant particles are removed from the surface of the patterning mask 205c by the corresponding particle-removing process based on the image of the surface of the patterning mask 205c.

If the controller 250 determines that the contaminant particles are removed from the surface of the patterning mask 205c by the corresponding particle-removing process, the method further includes an operation S350 as shown in FIG. 3. In operation S350, the controller 250 is configured to associate the corresponding particle-removing process with the type of the contaminant particles.

In some embodiments, the controller 250 is further configured to associate one or more attributes of the image of the patterning mask 205c with the image of the patterning mask 205c.

In some embodiments, the association between the corresponding particle-removing process and the type of the contaminant particles is saved in a database. In some embodiments, the association between the one or more attributes of the image of the patterning mask 205c and the image of the patterning mask 205c is also saved in the database.

If the controller 250 determines that the contaminant particles are not removed from the surface of the patterning mask 205c by the corresponding particle-removing process, the method proceeds to repeat operations S320, S330, and S340 as shown in FIG. 3.

The controller 250 is configured to determine different attributes that are used for determining and/or identifying the type of the contaminant particles on the surface of the patterning mask 205c when repeating operation S320. The controller 250 is also configured to adjust parameters of the corresponding particle-removing process when repeating operation S330. The parameters of the corresponding particle-removing process include a temperature of the SPM, a duration of the SPM, a pressure of the air blade, and a type of the alkaline media after determining that the contaminant particles are not removed from the surface of the patterning mask 205c by the corresponding particle-removing process.

In some embodiments, the patterning mask 205c is transported away from the exposure device 200 into a repair and clean apparatus (not shown) to perform method 300. In some embodiments, the method further includes an operation to record the patterning mask 202 as clean and release the patterning mask 205c from the repair and clean apparatus for use in manufacturing operations after associating the corresponding particle-removing process with the type of the contaminant particles. In some embodiments, the operation to release the patterning mask 205c is performed after associating the corresponding particle-removing process with the type of the contaminant particles.

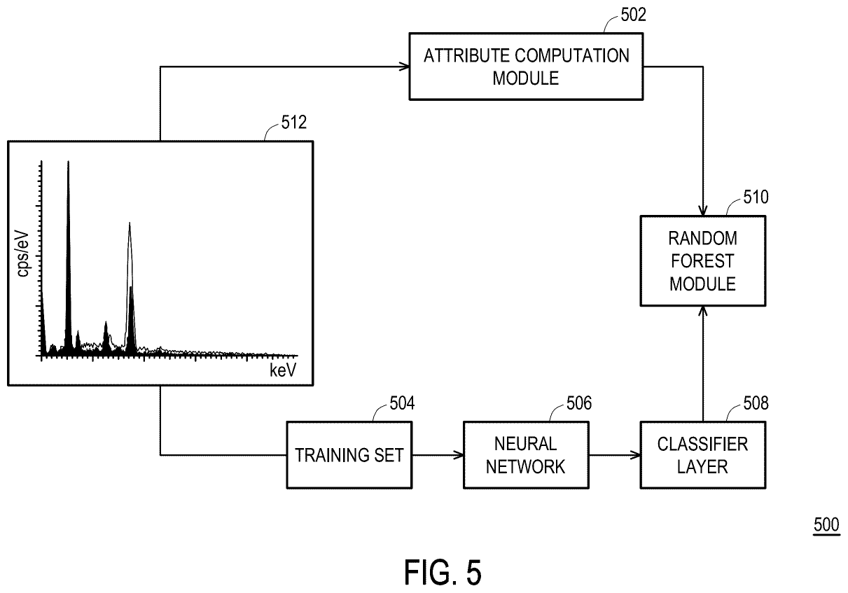

FIG. 5 illustrates a block diagram of an example artificial intelligence (AI) engine 500 according to various aspects of the present disclosure. In some embodiments, the AI engine 500 is implemented as a part of method 300. As shown in FIG. 5, the AI engine 500 comprises an attribute computation module 502, a training set 504, a neural network 506, a classifier layer 508, and a random forest module 510.

In some embodiments, an image 512 is fed into the AI engine 500 and received by the attribute computation module 502 and training set 504 in parallel. In an upper portion of the AI engine 500, the attribute computation module 502 may calculate attributes of the image 512 such as the size of the contaminant particles, the shape of the contaminant particles, the viscosity of the contaminant particles, and components of the contaminant particles, etc. While in a lower portion of the AI engine, the training set 504 provides suitable images for comparative analysis with the image 512. The training set 504 provides an example patterning mask image, which contains different contaminant particles on the surface of the patterning mask that previously occurred and were saved in a database. The example patterning mask image is processed by the neural network 506 (e.g., a ResNet 18 network) to generate attributes. In some embodiments, the neural network 506 includes at least one convolution layer and/or a depth-wise separable convolution layer for computing attributes. In some embodiments, there are a large set of attributes, in which case the classifier layer 508 determines and selects the best attributes for additional analysis. In an embodiment, the classifier layer 508 includes at least one fully connected (FC) layer for attribute selection. The classifier layer 508 is implemented as multiple stages, each of which may reduce the number of attributes. The classifier layer 508 determines and outputs a detection probability (embedded with other attributes), which is connected to the random forest module 510 to output a final detection probability. Therefore, the random forest module 510 mixes or combines both outputs of the attribute computation module 502 and the classifier layer 508 in generating the final detection probability. The final detection probability is used to determine the detectability of contaminant particles (e.g., a probability of one means detection, while a probability of zero means no detection) on the surface of the patterning mask 505c. Thus, the final detection probability may be used in method 300 to help optimize or retrain the contaminant particle-removing process.

The upper portion of the AI engine 500 containing the attribute computation module 502 is sometimes called a machine learning portion, while the lower portion of the AI engine 500 containing the training set 504, the neural network 506, and the classifier layer 508 may be called a deep learning portion. The image 512 may represent a simulated image (e.g., when the AI engine 500 is used for contaminant particle-removing process optimization) or an actual inspection image (e.g., when the AI engine 500 is being trained based on a database which includes images of patterning masks having known contaminant particles on the surface of the patterning masks, in which case the output detection probability may determine the effectiveness of the AI engine 500). The AI engine determines the type of the contaminant particles based on the image of the patterning mask. In addition, the AI engine 500 may also help optimize the contaminant particle-removing process using the final detection probability.

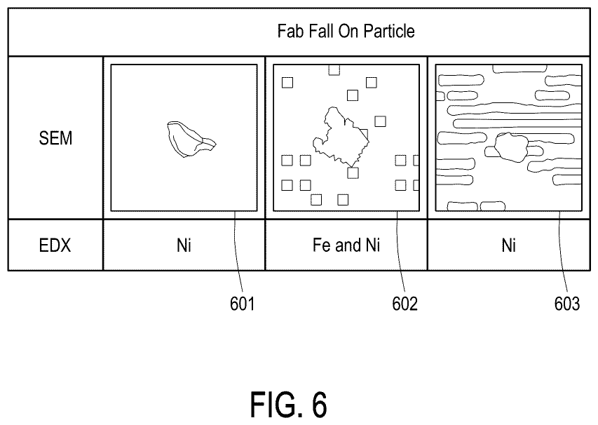

FIG. 6 illustrates examples of surface profiles of patterning masks according to embodiments of the disclosure. As shown in FIG. 6, surface profiles of three patterning masks having contaminant particles on the surfaces of the patterning masks are imaged by scanning electron microscopy (SEM) and illustrated in line drawings. The left hand side of FIG. 6 shows a surface profile 601 having Ni particles on the surface of a patterning mask. The middle drawing shows a surface profile 602 having Fe and Ni particles on the surface of a patterning mask. The right hand side of FIG. 6 shows a surface profile 603 having Ni particles on the surface of a patterning mask.

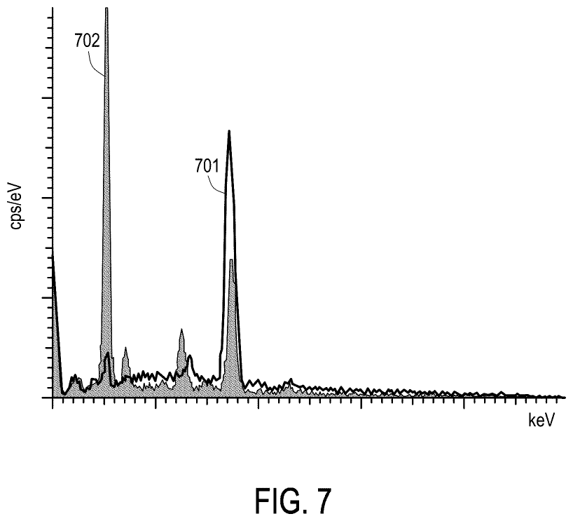

FIG. 7 illustrates surface spectrums of patterning masks according to embodiments of the disclosure. As shown in FIG. 7, a surface spectrum 701 and a surface spectrum 702 of two patterning masks having contaminant particles on the surface of the patterning mask are imaged by energy-dispersive X-ray spectroscopy (EDX) and illustrated. For example, as shown in FIG. 7, the contaminant particles on the surface of the patterning mask with surface spectrum 701 include Ta. For example, as shown in FIG. 7, the contaminant particles on the surface of the patterning mask with surface spectrum 702 include O and Si.

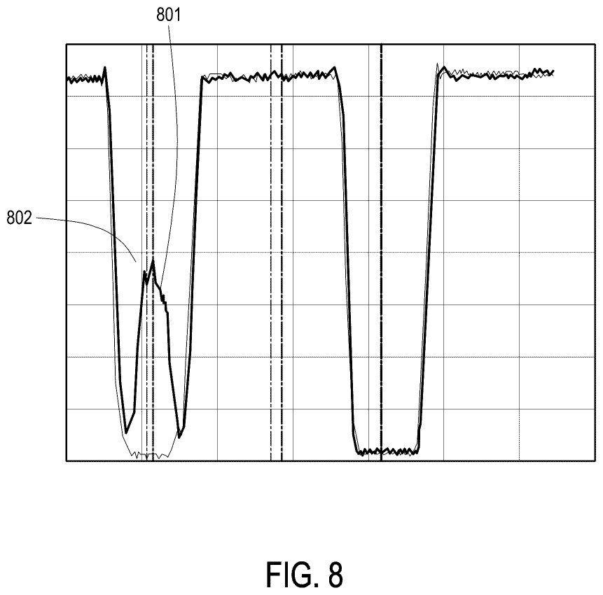

FIG. 8 illustrates an example of a surface profile 801 of a patterning mask according to embodiments of the disclosure. As shown in FIG. 8, the surface profile of the patterning mask having contaminant particles on the surface of the patterning mask is imaged by atomic force microscopy (AFM) and illustrated. For example, as shown in FIG. 8, the contaminant particles positioned in a valley 802 of the surface of the patterning mask have a size of about 50 nm.

FIGS. 9A and 9B illustrate a computer system 900 for implementing various methods described herein, in accordance with some embodiments of the present disclosure. In some embodiments, the computer system 900 is used for performing the functions of the controller 250 of FIG. 2, steps of method 300 of FIG. 3, and the functions of AI engine 500 of FIG. 5

FIG. 9A is a schematic view of a computer system that performs the functions of an apparatus for cleaning the components of the lithography system. All of or a part of the processes, methods, and/or operations of the foregoing embodiments can be realized using computer hardware and computer programs executed thereon. In FIG. 9A, a computer system 900 is provided with a computer 901 including an optical disk read only memory (e.g., CD-ROM or DVD-ROM) drive 905 and a magnetic disk drive 906, a keyboard 902, a mouse 903, and a monitor 904.

FIG. 9B is a diagram showing an internal configuration of the computer system 900. In FIG. 9B, the computer 901 is provided with, in addition to the optical disk drive 905 and the magnetic disk drive 906, one or more processors, such as a micro processing unit (MPU) 911, a ROM 912 in which a program such as a boot up program is stored, a random access memory (RAM) 913 that is connected to the MPU 911 and in which a command of an application program is temporarily stored and a temporary storage area is provided, a hard disk 914 in which an application program, a system program, and data are stored, and a bus 915 that connects the MPU 911, the ROM 912, and the like. Note that the computer 901 may include a network card (not shown) for providing a connection to a LAN.

The program for causing the computer system 900 to execute the functions for removing contaminant particles on the patterning mask of the lithography system in the foregoing embodiments may be stored in an optical disk 921 or a magnetic disk 922, which are inserted into the optical disk drive 905 or the magnetic disk drive 906, and transmitted to the hard disk 914. Alternatively, the program may be transmitted via a network (not shown) to the computer 901 and stored in the hard disk 914. At the time of execution, the program is loaded into the RAM 913. The program may be loaded from the optical disk 921 or the magnetic disk 922, or directly from a network. The program does not necessarily have to include, for example, an operating system (OS) or a third-party program to cause the computer 901 to execute the functions of the control system for removing contaminant particles on the patterning mask of the lithography system in the foregoing embodiments. The program may only include a command portion to call an appropriate function (module) in a controlled mode and obtain desired results.

The novel processing systems and the methods according to the present disclosure provide an improved processing apparatus and methods for removing contaminant particles from the patterning mask, thereby reducing the mask cleaning time and the system maintenance time. Embodiments of the disclosure provide systems and methods using artificial intelligence (AI) to assist with determining and identifying the type of contaminant particles on the patterning mask, and further selecting a corresponding particle-removing process to remove the contaminant particles from the patterning mask. Consequently, accuracy and efficiency for identifying the type of contaminant particles and selecting the corresponding particle-removing process can be improved.

According to some embodiments of the present disclosure, a method for removing contaminant particles on a surface of a mask includes a) collecting an image of the mask with the contaminant particles on the surface of the mask, and b) determining a type of the contaminant particles based on the image of the mask. The method further includes c) performing a particle-removing process corresponding to the type of the contaminant particles on the surface of the mask, and d) determining if the contaminant particles are removed from the surface of the mask by the particle-removing process. The method also includes e) associating the particle-removing process with the type of the contaminant particles when the contaminant particles are removed from the surface of the mask by the particle-removing process. In an embodiment, the method further includes repeating steps b), c), and d) when the contaminant particles are not removed from the surface of the mask by the particle-removing process. In an embodiment, when repeating step b), different attributes are used for determining the type of the contaminant particles on the surface of the mask, and when repeating step c), parameters of the particle-removing process are adjusted. In an embodiment, associating the particle-removing process with the type of the contaminant particles includes associating the parameters of the particle-removing process with the type of the contaminant particles. In an embodiment, the type of the contaminant particles includes a size of the contaminant particles, a shape of the contaminant particles, a viscosity of the contaminant particles, and components of the contaminant particles. In an embodiment, the particle-removing process includes at least one of a sulfuric acid and hydrogen peroxide mixture (SPM) cleaning process, an air-blade cleaning process, and an alkaline media cleaning process. In an embodiment, the image of the mask is collected by an imaging device, wherein the imaging device includes at least one of an atomic force microscope (AFM), an energy-dispersive X-ray spectroscope (EDX), and a scanning electron microscope (SEM). In an embodiment, the method further includes recording the patterning mask as clean after associating the particle-removing process with the type of the contaminant particles.

According to some embodiments of the present disclosure, a method for removing contaminant particles on a surface of a mask includes collecting an image of the mask with the contaminant particles on the surface of the mask; and providing the image of the mask with the contaminant particles to an artificial intelligence engine. The method further includes determining, by the artificial intelligence engine, a type of the contaminant particles based on the image of the mask; and performing a particle-removing process corresponding to the type of the contaminant particles on the surface of the mask.

According to some embodiments of the present disclosure, a system for removing contaminant particles on a surface of a mask includes a processor; and a non-transitory computer readable storage medium storing a program. The processor is programmed to: a) collect an image of the mask with the contaminant particles on the surface of the mask, and b) determine a type of the contaminant particles based on the image of the mask. The program is further programmed to c) control a particle-removing process corresponding to the type of the contaminant particles on the surface of the mask, and d) determine if the contaminant particles are removed from the surface of the mask by the particle-removing process. The program is further programmed to e) associate the particle-removing process with the type of the contaminant particles when the contaminant particles are removed from the surface of the mask by the particle-removing process.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for removing contaminant particles on a surface of a mask, comprising:
a) collecting an image of the mask with the contaminant particles on the surface of the mask;
b) determining a type of the contaminant particles based on the image of the mask;
c) performing a particle-removing process corresponding to the type of the contaminant particles on the surface of the mask;
d) determining if the contaminant particles are removed from the surface of the mask by the particle-removing process; and
e) associating the particle-removing process with the type of the contaminant particles when the contaminant particles are removed from the surface of the mask by the particle-removing process.

2. The method according to claim 1, further comprising repeating steps b), c), and d) when the contaminant particles are not removed from the surface of the mask by the particle-removing process.

3. The method according to claim 2, wherein:
when repeating step b), different attributes are used for determining the type of the contaminant particles on the surface of the mask, and
when repeating step c), parameters of the particle-removing process are adjusted.

4. The method according to claim 3, wherein associating the particle-removing process with the type of the contaminant particles includes associating the parameters of the particle-removing process with the type of the contaminant particles.

5. The method according to claim 1, wherein:
the type of the contaminant particles includes a size of the contaminant particles, a shape of the contaminant particles, a viscosity of the contaminant particles, and components of the contaminant particles.

6. The method according to claim 1, wherein:
the particle-removing process includes at least one of a sulfuric acid and hydrogen peroxide mixture (SPM) cleaning process, an air-blade cleaning process, and an alkaline media cleaning process.

7. The method according to claim 1, wherein:
the image of the mask is collected by an imaging device, wherein the imaging device includes at least one of an atomic force microscope (AFM), an energy-dispersive X-ray spectroscope (EDX), and a scanning electron microscope (SEM).

8. The method according to claim 1, further comprising:
recording the mask as clean after associating the particle-removing process with the type of the contaminant particles.

9. A method for removing contaminant particles on a surface of a mask, comprising:
collecting an image of the mask with the contaminant particles on the surface of the mask;
providing the image of the mask with the contaminant particles to an artificial intelligence engine;
determining, by the artificial intelligence engine, a type of the contaminant particles based on the image of the mask; and
performing a particle-removing process corresponding to the type of the contaminant particles on the surface of the mask.

10. The method according to claim 9, wherein:
the type of the contaminant particles includes a size of the contaminant particles, a shape of the contaminant particles, a viscosity of the contaminant particles, and components of the contaminant particles.

11. The method according to claim 9, wherein:
the particle-removing process includes at least one of a sulfuric acid and hydrogen peroxide mixture (SPM) cleaning process, an air-blade cleaning process, and an alkaline media cleaning process.

12. The method according to claim 9, wherein:
the image of the mask is collected by an imaging device, wherein the imaging device includes at least one of an atomic force microscope (AFM), an energy-dispersive X-ray spectroscope (EDX), and a scanning electron microscope (SEM).

13. The method according to claim 9, further comprising recording the mask as clean after associating the particle-removing process with the type of the contaminant particles.

14. An apparatus for removing contaminant particles on a surface of a mask, comprising:
a processor; and a non-transitory computer readable storage medium storing a program, wherein the processor is programmed to:
a) collect an image of the mask with the contaminant particles on the surface of the mask;
b) determine a type of the contaminant particles based on the image of the mask;
c) control a particle-removing process corresponding to the type of the contaminant particles on the surface of the mask;
d) determine if the contaminant particles are removed from the surface of the mask by the particle-removing process; and
e) associate the particle-removing process with the type of the contaminant particles when the contaminant particles are removed from the surface of the mask by the particle-removing process.

15. The apparatus according to claim 14, wherein the processor is further programmed to repeat steps b), c), and d) when the contaminant particles are not removed from the surface of the mask by the particle-removing process.

16. The apparatus according to claim 15, wherein:
when repeating step b), different attributes are used for determining the type of the contaminant particles on the surface of the mask, and
when repeating step c), parameters of the particle-removing process are adjusted.

17. The apparatus according to claim 16, wherein associating the particle-removing process with the type of the contaminant particles includes associating the parameters of the particle-removing process with the type of the contaminant particles.

18. The apparatus according to claim 14, wherein:
the type of the contaminant particles includes a size of the contaminant particles, a shape of the contaminant particles, a viscosity of the contaminant particles, and components of the contaminant particles.

19. The apparatus according to claim 14, wherein the processor is programmed to control at least one of a sulfuric acid and hydrogen peroxide mixture (SPM) cleaning process, an air-blade cleaning process, and an alkaline media cleaning process.

20. The apparatus according to claim 14, further comprising an imaging device for collecting the image of the mask is collected by an imaging device selected from the group consisting of at least one of an atomic force microscope (AFM), an energy-dispersive X-ray spectroscope (EDX), and a scanning electron microscope (SEM).
